(19) United States
(12) Patent Application Publication
(10) Pub. No.: US 2025/0272818 A1
(43) Pub. Date: Aug. 28, 2025

(54) DEVICE, SYSTEM, AND METHOD

(71) Applicant: TOYOTA JIDOSHA KABUSHIKI KAISHA, Toyota-shi (JP)

(72) Inventors: Yasuyoshi Hatano, Nisshin-shi (JP); Kento Iwahori, Nisshin-shi (JP); Daiki Yokoyama, Miyoshi-shi (JP); Yasuhiro Saito, Toyoake-shi (JP)

(73) Assignee: TOYOTA JIDOSHA KABUSHIKI KAISHA, Toyota-shi (JP)

(21) Appl. No.: 19/045,806

(22) Filed: Feb. 5, 2025

(30) Foreign Application Priority Data
Feb. 22, 2024 (JP) 2024-025047

(51) Int. Cl. G06T 7/00; G05D 1/221; G05D 107/70; G05D 109/10; G06F 30/15; G06T 7/20; G06T 7/70

(52) U.S. Cl. CPC G06T 7/0004; G05D 1/221; G06F 30/15; G06T 7/20; G06T 7/70; G05D 2107/70; G05D 2109/10; G06T 2207/10028; G06T 2207/30252

(57) ABSTRACT

A device includes: an appearance information acquisition unit configured to acquire measured appearance information on an appearance of a mobile body; a movement information acquisition unit configured to acquire movement information on movement of the mobile body; a determination unit configured to determine whether a deficiency has occurred in the measured appearance information; a complement unit configured to, in a case where the determination unit determines that the deficiency has occurred, use the movement information to complement the deficiency in the measured appearance information; and an estimation unit configured to estimate at least one of a position and an orientation of the mobile body by comparing reference appearance information on the appearance of the mobile body with the measured appearance information, and, in a case where the determination unit determines that the deficiency has occurred, compare the complemented measured appearance information with the reference appearance information.

### CROSS-REFERENCE TO RELATED APPLICATION

This application claims priority to Japanese Patent Application No. 2024-025047 filed on Feb. 22, 2024. The disclosure of the above-identified application, including the specification, drawings, and claims, is incorporated by reference herein in its entirety.

### BACKGROUND

### 1. Technical Field

The present disclosure relates to a device, a system, and a method for estimating at least one of a position and an orientation of a mobile body.

### 2. Description of Related Art

In a vehicle manufacturing process, a technique of causing a vehicle to travel via unmanned driving is known (for example, Japanese Unexamined Patent Application Publication No. 2017-538619 (JP 2017-538619 A)).

### SUMMARY

When a mobile body, such as a vehicle, is moved by unmanned driving, processing of estimating a position or an orientation of the mobile body is executed. The position or the orientation of the mobile body can be estimated by comparing measurement information acquired by using a detector, such as a camera or a light detection and ranging (LiDAR), with reference information prepared in advance. However, in a case where a deficiency has occurred in the measurement information, when the measurement information is directly used to execute the estimation processing, there is a possibility that a correct estimation result cannot be obtained.

The present disclosure can be implemented as the following aspects.

(1) A first aspect of the present disclosure provides a device. The device includes an appearance information acquisition unit, a movement information acquisition unit, a determination unit, a complement unit, and an estimation unit. The appearance information acquisition unit is configured to acquire measured appearance information on an appearance of a mobile body from a detector configured to measure the appearance of the mobile body. The movement information acquisition unit is configured to acquire movement information on movement of the mobile body. The determination unit is configured to determine whether a deficiency has occurred in the measured appearance information. The complement unit is configured to, in a case where the determination unit determines that the deficiency has occurred, use the movement information to complement the deficiency in the measured appearance information. The estimation unit is configured to estimate at least one of a position and an orientation of the mobile body by comparing reference appearance information on the appearance of the mobile body with the measured appearance information. The estimation unit is configured to, in a case where the determination unit determines that the deficiency has occurred, compare the measured appearance information complemented by the complement unit with the reference appearance information.

With the device according to the aspect, the deficiency in the measured appearance information can be complemented. Therefore, a situation can be suppressed in which a correct estimation result of the position or the orientation of the mobile body cannot be obtained due to the occurrence of the deficiency in the measured appearance information.

(2) In the device according to the above-described aspect, the determination unit may be configured to, in a case where the deficiency is detected from the measured appearance information, determine that the deficiency has occurred in the measured appearance information.

With the device according to the aspect, in a case where the deficiency is detected from the measured appearance information, the deficiency in the measured appearance information can be complemented.

(3) In the device according to the above-described aspect, the determination unit may be configured to, in a case where the determination unit predicts that the deficiency will occur in the measured appearance information, determine that the deficiency has occurred in the measured appearance information.

With the device according to the aspect, the deficiency in the measured appearance information can be complemented in a case where the occurrence of the deficiency in the measured appearance information is predicted.

(4) In the device according to the above-described aspect, the determination unit may be configured to, in at least one of a case where the mobile body is located at a predetermined place and a case where the mobile body passes through the predetermined place, predict that the deficiency will occur in the measured appearance information.

With the device according to the aspect, the prediction can be easily made that the deficiency will occur in the measured appearance information.

(5) In the device according to the above-described aspect, the predetermined place may be a place where a predetermined number of workers are present.

With the device according to the aspect, a situation can be suppressed in which a correct estimation result of the position or the orientation of the mobile body cannot be obtained in a place where a blind spot is likely to occur in the detector due to the worker.

(6) In the device according to the above-described aspect, the predetermined place may be a place where the worker gets on the mobile body to perform work.

With the device according to the aspect, a situation can be suppressed in which a correct estimation result of the position or the orientation of the mobile body cannot be obtained in a place where a blind spot is likely to occur in the detector due to the worker.

(7) The device according to the above-described aspect may further include a controller configured to, in a case where the complement of the deficiency in the measured appearance information is repeated a predetermined number of times, decelerate or stop the mobile body.

With the device according to the aspect, the decrease in the estimation accuracy can be suppressed by repeating the complement.

(8) In the device according to the above-described aspect, the controller may be configured to change the predetermined number of times in accordance with a movement state of the mobile body.

With the device according to the aspect, a situation can be suppressed in which the movement state of the mobile body is unstable.

(9) In the device according to the above-described aspect, the controller may be configured to change the predetermined number of times in accordance with magnitude of the deficiency.

With the device according to the aspect, the estimation accuracy is likely to be decreased as the magnitude of the deficiency in the measured appearance information is increased, and thus a significant decrease in the estimation accuracy can be suppressed by changing the predetermined number of times in accordance with the magnitude of the deficiency.

(10) In the device according to the above-described aspect, the controller may be configured to change the predetermined number of times in accordance with a distance between the detector and the mobile body.

With the device according to the aspect, the estimation accuracy is likely to be decreased as the distance between the detector and the mobile body is increased, and thus a significant decrease in the estimation accuracy can be suppressed by changing the predetermined number of times in accordance with the distance between the detector and the mobile body.

(11) A second aspect of the present disclosure provides a system. The system includes a detector, an appearance information acquisition unit, a movement information acquisition unit, a determination unit, a complement unit, and an estimation unit. The detector is configured to measure an appearance of a mobile body. The appearance information acquisition unit is configured to acquire measured appearance information on the appearance of the mobile body from the detector. The movement information acquisition unit is configured to acquire movement information on movement of the mobile body. The determination unit is configured to determine whether a deficiency has occurred in the measured appearance information. The complement unit is configured to, in a case where the determination unit determines that the deficiency has occurred, use the movement information to complement the deficiency in the measured appearance information. The estimation unit is configured to estimate at least one of a position and an orientation of the mobile body by comparing reference appearance information on the appearance of the mobile body with the measured appearance information. The estimation unit is configured to, in a case where the determination unit determines that the deficiency has occurred, compare the measured appearance information complemented by the complement unit with the reference appearance information.

With the system according to the aspect, the deficiency in the measured appearance information can be complemented. Therefore, a situation can be suppressed in which a correct estimation result of the position or the orientation of the mobile body cannot be obtained due to the occurrence of the deficiency in the measured appearance information.

(12) A third aspect of the present disclosure provides a method. The method includes acquiring measured appearance information on an appearance of a mobile body by measuring the appearance of the mobile body, acquiring movement information on movement of the mobile body, determining whether a deficiency has occurred in the measured appearance information, complementing, in a case where a determination is made that the deficiency has occurred, the deficiency in the measured appearance information by using the movement information, estimating, in a case where a determination is made that the deficiency has occurred, at least one of a position and an orientation of the mobile body by comparing the complemented measured appearance information with reference appearance information on the appearance of the mobile body.

According to the method according to the aspect, the deficiency in the measured appearance information can be complemented. Therefore, a situation can be suppressed in which a correct estimation result of the position or the orientation of the mobile body cannot be obtained due to the occurrence of the deficiency in the measured appearance information.

The present disclosure can also be implemented in various aspects other than the device and the method. For example, the method can be implemented in an aspect of a system, a computer program, a recording medium on which a computer program is recorded, or the like.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a diagram showing a configuration of a system according to a first embodiment;

FIG. 2 is a diagram showing a configuration of a vehicle according to the first embodiment;

FIG. 3 is a diagram showing a configuration of a server device according to the first embodiment;

FIG. 4 is a diagram showing a state in which a vehicle is moved by remote control in a factory;

FIG. 5 is a flowchart showing a processing procedure of traveling control of the vehicle according to the first embodiment;

FIG. 6 is a diagram showing a deficiency in measured appearance information;

FIG. 7 is a diagram showing contents of movement information;

FIG. 8 is a diagram showing a method of detecting the deficiency in the measured appearance information;

FIG. 9 is a diagram showing a method of complementing the deficiency in the measured appearance information;

FIG. 10 is a diagram showing a configuration of a system according to a second embodiment;

FIG. 11 is a diagram showing a configuration of a vehicle according to the second embodiment; and

FIG. 12 is a flowchart showing a processing procedure of traveling control of the vehicle according to the second embodiment.

### DETAILED DESCRIPTION OF EMBODIMENTS

### A. First Embodiment

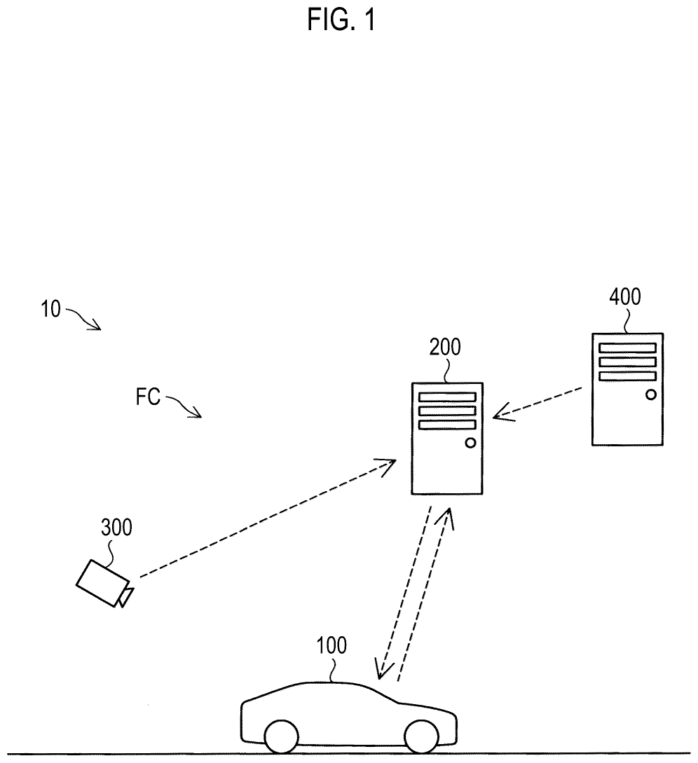

FIG. 1 is a diagram showing a configuration of a system 10 according to a first embodiment. In the present embodiment, the system 10 is used in a factory that manufactures a mobile body and is used to move the mobile body via unmanned driving. In the present embodiment, the system 10 includes a vehicle 100, a server device 200, at least one external sensor 300, and a process management device 400. In the present embodiment, the vehicle 100 can be regarded as a “mobile body” according to the present disclosure. The server device 200 can be regarded as a “device” according to the present disclosure. The external sensor 300 can be regarded as a “detector” according to the present disclosure.

In the present disclosure, the “mobile body” means a movable body, for example, a vehicle or an electric vertical take-off and landing aircraft (so-called flying car). The vehicle may be a vehicle that travels using wheels or a vehicle that travels using a caterpillar, and is, for example, a passenger car, a truck, a bus, a two-wheeled vehicle, a four-wheeled vehicle, a tank, and a construction vehicle. The vehicle includes a battery electric vehicle (BEV), a gasoline vehicle, a hybrid electric vehicle, and a fuel cell electric vehicle. In a case where the mobile body is other than the vehicle, the expression of “vehicle” and “car” according to the present disclosure can be replaced with “mobile body” as appropriate, and the expression of “travel” can be replaced with “move” as appropriate.

In the present disclosure, the “unmanned driving” means driving that does not depend on a traveling operation performed by an occupant. The traveling operation means an operation related to at least any one of “traveling”, “turning”, and “stopping” of the vehicle 100. The unmanned driving is implemented by automatic or manual remote control using a device located outside the vehicle 100 or by autonomous control of the vehicle 100. The occupant who does not perform the traveling operation may get on the vehicle 100 that travels via the unmanned driving. Examples of the occupant who does not perform the traveling operation include a person who simply sits on a seat of the vehicle 100 and a person who performs work different from the traveling operation, such as assembly, inspection, or operation of switches, in a state of getting on the vehicle 100. The driving via the traveling operation performed by the occupant may be referred to as “manned driving”.

In the present disclosure, the “remote control” includes “complete remote control” in which all the operations of the vehicle 100 are completely decided from the outside of the vehicle 100, and “partial remote control” in which a part of the operations of the vehicle 100 is decided from the outside of the vehicle 100. In addition, the “autonomous control” includes “complete autonomous control” in which the vehicle 100 autonomously controls the operation thereof without receiving any information from an external device of the vehicle 100, and “partial autonomous control” in which the vehicle 100 autonomously controls the operation thereof by using the information received from the external device of the vehicle 100.

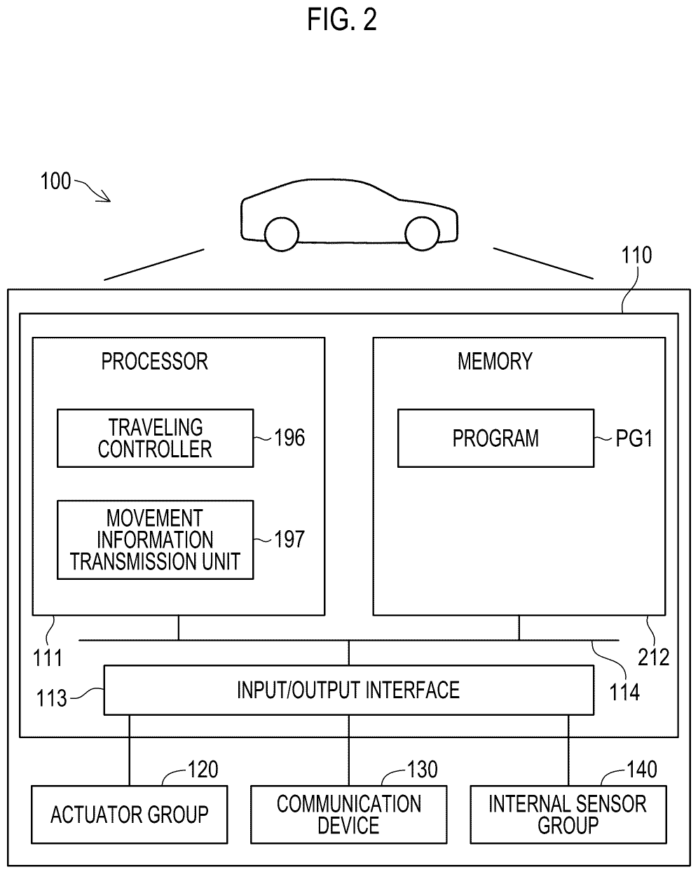

FIG. 2 is a diagram showing a configuration of the vehicle 100. In the present embodiment, the vehicle 100 is a battery electric vehicle and is configured to travel via the remote control. The vehicle 100 includes a vehicle control device 110 that controls the respective units of the vehicle 100, an actuator group 120 that is driven under control of the vehicle control device 110, a communication device 130 that communicates with the server device 200 via wireless communication, and an internal sensor group 140.

The actuator group 120 includes at least one actuator. In the present embodiment, the actuator group 120 includes an actuator of a drive device that generates a propulsion force of the vehicle 100, an actuator of a steering device that changes a traveling direction of the vehicle 100, and an actuator of a brake device that generates a brake force of the vehicle 100. In the present embodiment, the drive device includes a battery, a traveling motor driven by an electric power of the battery, and wheels rotated by the traveling motor. The actuator of the drive device includes the traveling motor.

The internal sensor group 140 includes at least one internal sensor. The internal sensor is a sensor mounted in the vehicle 100. In the present embodiment, the internal sensor group 140 includes a vehicle speed sensor for detecting a speed of the vehicle 100 and a steering angle sensor for detecting a steering angle of the vehicle 100 as the internal sensors.

The vehicle control device 110 is configured by a computer including a processor 111, a memory 112, an input/output interface 113, and an internal bus 114. The processor 111, the memory 112, and the input/output interface 113 are connected to be bidirectionally communicable with each via the internal bus 114. The actuator group 120, the communication device 130, and the internal sensor group 140 are connected to the input/output interface 113.

The processor 111 functions as a traveling controller 196 and a movement information transmission unit 197 by executing a computer program PG1 stored in advance in the memory 112.

The traveling controller 196 controls the actuator group 120. The traveling controller 196 can cause the vehicle 100 to travel by controlling the actuator group 120 in response to the operation performed by the occupant in a case where the occupant gets on the vehicle 100. The traveling controller 196 can cause the vehicle 100 to travel by controlling the actuator group 120 using a traveling control signal received from the server device 200 regardless of whether the occupant gets on the vehicle 100. In the present embodiment, the acceleration and the steering angle of the vehicle 100 are included in the traveling control signal as parameters. In another embodiment, the speed of the vehicle 100 may be included in the traveling control signal as the parameter instead of the acceleration of the vehicle 100 or in addition to the acceleration of the vehicle 100.

The movement information transmission unit 197 acquires a measurement result from the internal sensor group 140 and transmits the measurement result of the internal sensor group 140 to the server device 200. In the present embodiment, the movement information transmission unit 197 repeatedly executes, at a predetermined cycle, the acquisition of the measurement result and the transmission of the measurement result. The measurement result of the internal sensor group 140 includes the speed of the vehicle 100 measured by the vehicle speed sensor included in the internal sensor group 140, the steering angle of the vehicle 100 measured by the steering angle sensor included in the internal sensor group 140, and measurement times of the speed and the steering angle.

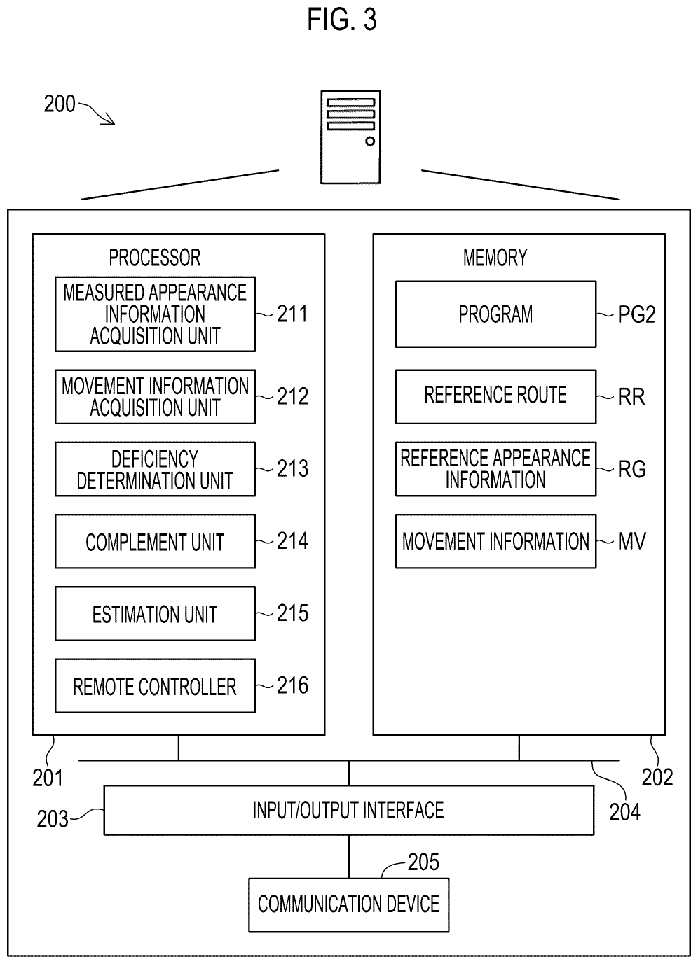

FIG. 3 is a diagram showing a configuration of the server device 200. The server device 200 is configured by a computer including a processor 201, a memory 202, an input/output interface 203, and an internal bus 204. The processor 201, the memory 202, and the input/output interface 203 are connected to be bidirectionally communicable with each via the internal bus 204. The communication device 205 for communicating with the vehicle 100 via wireless communication is connected to the input/output interface 203. In the present embodiment, the communication device 205 can further communicate with the external sensor 300 and the process management device 400 via wired communication or wireless communication.

The processor 201 functions as a measured appearance information acquisition unit 211, a movement information acquisition unit 212, a deficiency determination unit 213, a complement unit 214, an estimation unit 215, and a remote controller 216 by executing a computer program PG2 stored in advance in the memory 202. In the present embodiment, the remote controller 216 can be regarded as a “controller” according to the present disclosure.

The measured appearance information acquisition unit 211 acquires measured appearance information MG from the external sensor 300. The measured appearance information MG is information on the appearance of the vehicle 100, and is information obtained by measuring the vehicle 100. In the present embodiment, the external sensor 300 is a LiDAR, and the measured appearance information is three-dimensional point cloud data.

The movement information acquisition unit 212 acquires the measurement result of the internal sensor group 140 from the vehicle 100, and records the measurement result of the internal sensor group 140 in the memory 202. In the present embodiment, the movement information acquisition unit 212 records, in time series, the measurement results of the internal sensor group 140 repeatedly transmitted from the vehicle 100 to the memory 202 at a predetermined cycle. In the following description, information on movement of the vehicle 100, such as the speed or the steering angle of the vehicle 100, will be referred to as movement information MV.

The deficiency determination unit 213 determines whether the deficiency has occurred in the measured appearance information MG acquired by the measured appearance information acquisition unit 211. The occurrence of the deficiency in the measured appearance information MG means that a part of the appearance of the vehicle 100 represented by the measured appearance information MG is deficient.

The complement unit 214 uses the movement information MV to complement the deficiency in the measured appearance information MG in a case where the deficiency determination unit 213 determines that the deficiency has occurred in the measured appearance information MG. In the present disclosure, the complement of the deficiency in the measured appearance information MG includes the complement of all the deficiencies in the measured appearance information MG, as well as the complement of a part of the deficiencies in the measured appearance information MG. That is, in the present disclosure, the complement of the deficiency in the measured appearance information MG means complement of at least a part of the deficiencies in the measured appearance information MG.

The estimation unit 215 estimates at least one of a position and an orientation of the vehicle 100 by comparing the measured appearance information MG with reference appearance information RG stored in advance in the memory 202. The reference appearance information RG is information on the appearance of the vehicle 100. In the present embodiment, the reference appearance information RG is three-dimensional point cloud data. The reference appearance information RG can be generated by using, for example, CAD data representing the appearance of the vehicle 100. The estimation unit 215 estimates both the position and the orientation of the vehicle 100. In a case where the deficiency determination unit 213 does not determine that the deficiency has occurred in the measured appearance information MG, the estimation unit 215 compares the measured appearance information MG in which the deficiency is not complemented by the complement unit 214 with the reference appearance information RG. In a case where the deficiency determination unit 213 determines that the deficiency has occurred in the measured appearance information MG, the estimation unit 215 compares the measured appearance information MG in which the deficiency is complemented by the complement unit 214 with the reference appearance information RG.

The remote controller 216 executes the remote control of the vehicle 100. The remote controller 216 generates the traveling control signal for causing the vehicle 100 to travel via the remote control by using the estimation result of the estimation unit 215. The remote controller 216 transmits the traveling control signal to the vehicle 100.

As shown in FIG. 1, the external sensor 300 is a sensor located outside the vehicle 100. The external sensor 300 measures the appearance of the vehicle 100 and generates the measured appearance information including the appearance of the vehicle 100. In the present embodiment, the external sensor 300 is a LiDAR, and the measured appearance information includes the three-dimensional point cloud data and a measurement time of the three-dimensional point cloud data. The external sensor 300 includes a communication device (not shown) and can communicate with the server device 200 via wired communication or wireless communication. The external sensor 300 transmits the measured appearance information to the server device 200 through the communication device. In the present embodiment, the external sensor 300 repeatedly executes, at a predetermined cycle, the generation of the measured appearance information and the transmission of the measured appearance information.

The process management device 400 executes management of an entire manufacturing process of the vehicle 100 in a factory FC. The process management device 400 is configured by at least one computer. The process management device 400 includes a database in which process information on the manufacturing process of the vehicle 100 is recorded. The process information includes, for example, identification information of the vehicle 100, the contents of the manufacturing process, and information on a progress status of the manufacturing process. The process management device 400 includes a communication device (not shown) and can communicate with the server device 200 via wired communication or wireless communication.

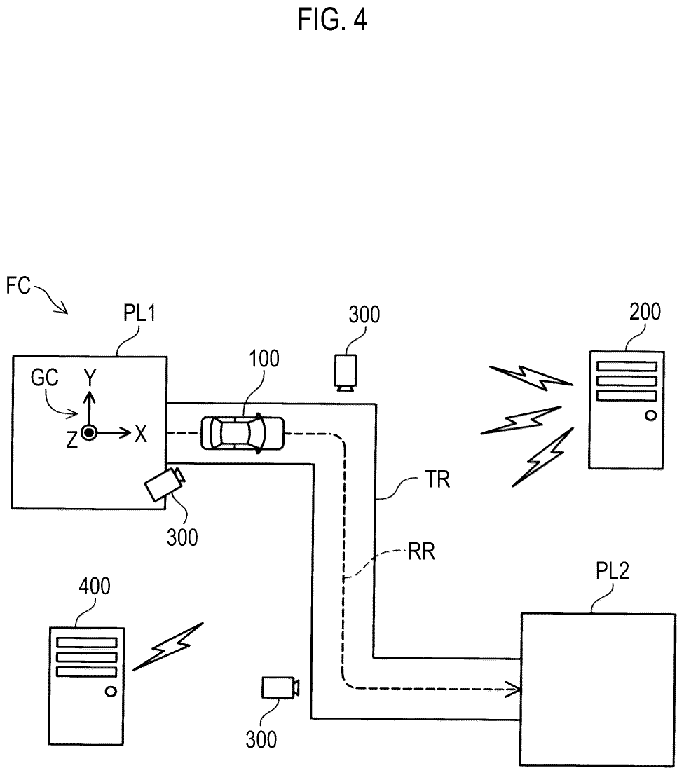

FIG. 4 is a diagram showing a state in which the vehicle 100 is moved by the remote control in the factory FC. In the present embodiment, the remote control of the vehicle 100 is executed in the factory FC that manufactures the vehicle 100. The factory FC includes a first place PL1 and a second place PL2. The first place PL1 is, for example, a place where the vehicle 100 is constructed, and the second place PL2 is, for example, a place where the vehicle 100 is inspected. The vehicle 100 constructed in the first place PL1 is in a state in which the vehicle 100 can travel via the remote control. The first place PL1 and the second place PL2 are connected by a track TR on which the vehicle 100 can travel. A plurality of external sensors 300 is installed in the vicinity of the track TR. The server device 200 can estimate the position and the orientation of the vehicle 100 by using the measurement result of the external sensor 300. The position and the orientation of the vehicle 100 in the factory FC can be expressed by using coordinates of X, Y, and Z in a global coordinate system GC. The server device 200 can generate the traveling control signal for causing the vehicle 100 to travel based on the estimation result of the position and the orientation of the vehicle 100, and transmit the traveling control signal to the vehicle 100. The vehicle 100 can travel in response to the received traveling control signal. Therefore, with the system 10, the vehicle 100 can be moved from the first place PL1 to the second place PL2 by the remote control without using a transport device, such as a crane or a conveyor. The vehicle 100 that has passed the inspection in the second place PL2 is then shipped from the factory FC.

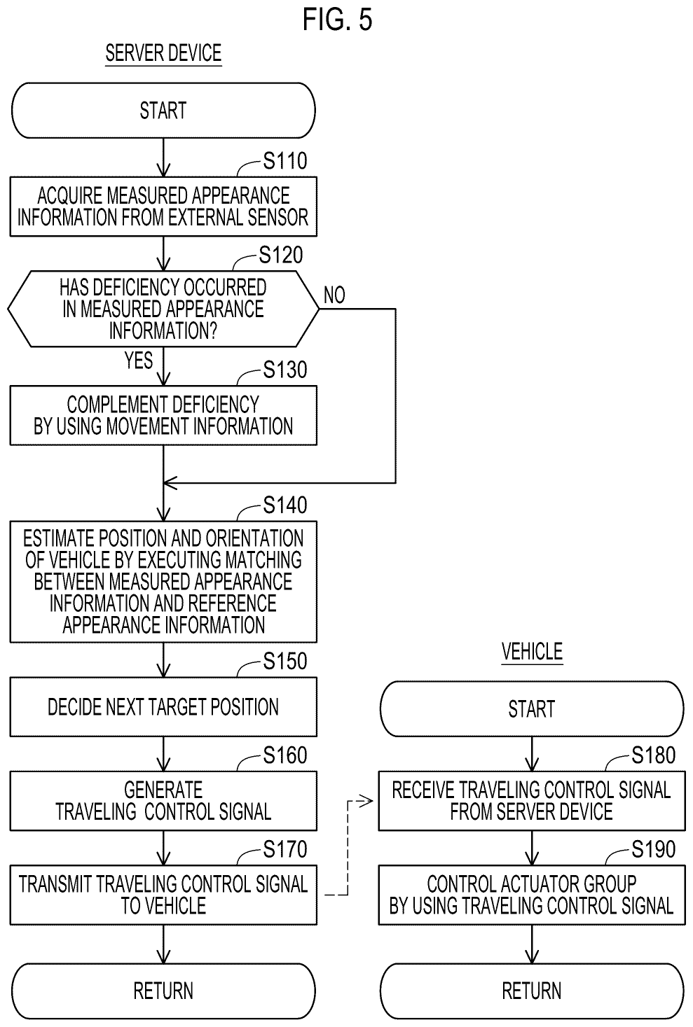

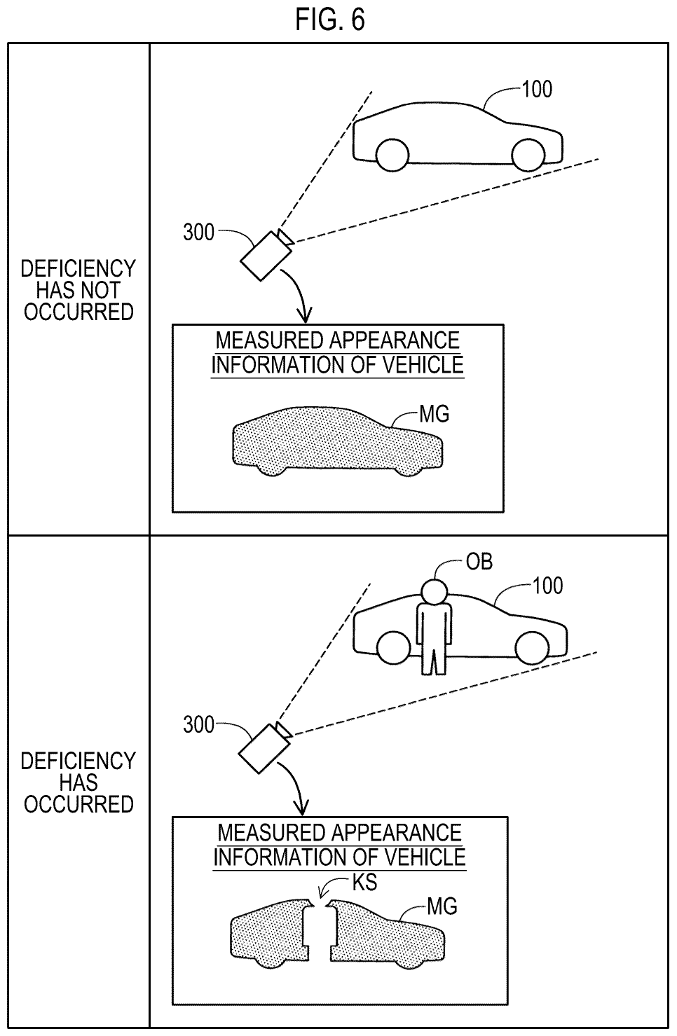

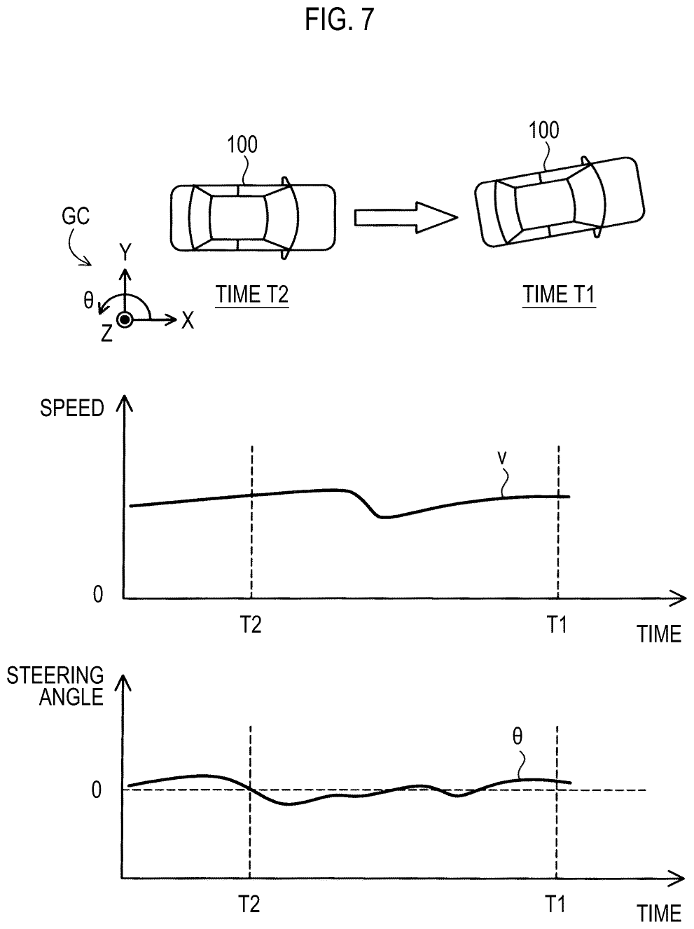

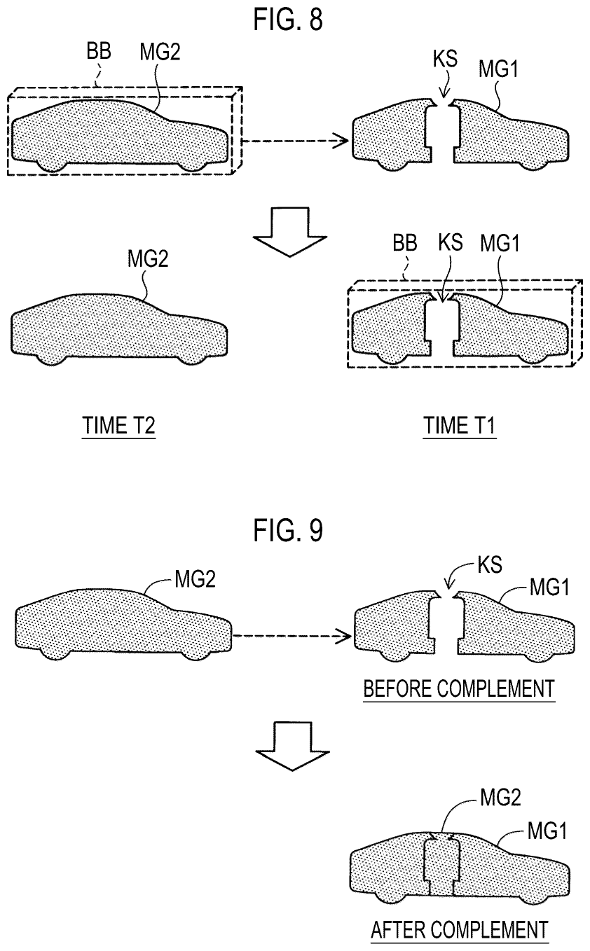

FIG. 5 is a flowchart showing a processing procedure of the traveling control of the vehicle 100. FIG. 6 is a diagram showing a deficiency KS in the measured appearance information MG. FIG. 7 is a diagram showing the contents of the movement information MV. FIG. 8 is a diagram showing a method of detecting the deficiency KS in the measured appearance information MG. FIG. 9 is a diagram showing a method of complementing the deficiency KS in the measured appearance information MG.

Steps S110 to S170 shown in FIG. 5 are repeatedly executed by the processor 201 of the server device 200. Steps S180 to S190 are repeatedly executed by the processor 111 of the vehicle control device 110. In step S110, the measured appearance information acquisition unit 211 acquires the measured appearance information MG from the external sensor 300. In the present embodiment, the measured appearance information MG is the three-dimensional point cloud data. The measured appearance information MG includes a point cloud of the vehicle 100 as a control target and a point cloud other than the point cloud of the vehicle 100. Examples of the point cloud other than the point cloud of the vehicle 100 include a point cloud of a road surface of the track TR, a point cloud of various facilities of the factory FC, and a point cloud of the worker of the factory FC.

In step S120, the deficiency determination unit 213 determines whether the deficiency KS has occurred in the measured appearance information MG. When a determination is made in step S120 that the deficiency KS has occurred in the measured appearance information MG, the deficiency determination unit 213 advances the processing to step S130. When a determination is not made in step S120 that the deficiency KS has occurred in the measured appearance information MG, the deficiency determination unit 213 skips step S130 and advances the processing to step S140. As shown in FIG. 6, in a case where an obstacle OB, such as a person or an object, is present between the external sensor 300 and the vehicle 100, a blind spot is generated in the external sensor 300 due to the obstacle OB, and the deficiency KS occurs in the measured appearance information MG. In the present embodiment, the deficiency determination unit 213 determines whether the deficiency KS has occurred in the measured appearance information MG by using at least one of the following determination methods A1 to A4.

### Determination Method A1

In the determination method A1, the deficiency determination unit 213 determines whether the deficiency KS has occurred in the measured appearance information MG by using the process information acquired from the process management device 400. In the manufacturing process in which a predetermined number or more of workers are present in the vicinity of the vehicle 100, there is a high possibility that the worker enters between the external sensor 300 and the vehicle 100, and the blind spot is generated in the external sensor 300 due to the worker. Therefore, the deficiency determination unit 213 determines that the deficiency KS has occurred in the measured appearance information MG in a case where the current manufacturing process of the vehicle 100 is the manufacturing process in which a predetermined number or more of workers are present in the vicinity of the vehicle 100. In the present embodiment, the process information includes information on a current manufacturing process of the vehicle 100 and information on the number of workers present in the vicinity of the vehicle 100 in the current manufacturing process. The deficiency determination unit 213 acquires the number of workers present in the vicinity of the vehicle 100 by using the process information acquired from the process management device 400, and determines that the deficiency KS has occurred in the measured appearance information MG in a case where the number of workers present in the vicinity of the vehicle 100 is equal to or more than a predetermined number. The deficiency determination unit 213 may acquire, in advance, the process information including information on a place where the manufacturing process is executed on the vehicle 100 and information on the number of workers present in the vicinity of the vehicle 100 in the place where the manufacturing process is executed on the vehicle 100 from the process management device 400, and determine that the deficiency KS has occurred in the measured appearance information MG in a case where the vehicle 100 passes through the place where the predetermined number or more of workers are present in the vicinity of the vehicle 100 and the manufacturing process is executed on the vehicle 100.

### Determination Method A2

In the determination method A2, the deficiency determination unit 213 determines whether the deficiency KS has occurred in the measured appearance information MG by using the process information acquired from the process management device 400. In the manufacturing process in which the worker gets on the vehicle 100 to perform the work, there is a high possibility that the blind spot is generated in the external sensor 300 due to the worker who gets on the vehicle 100. Therefore, the deficiency determination unit 213 determines that the deficiency KS has occurred in the measured appearance information MG in a case where the current manufacturing process of the vehicle 100 is the manufacturing process in which the worker gets on the vehicle 100 to perform the work. In the present embodiment, the process information includes information on the current manufacturing process of the vehicle 100 and information on whether the worker gets on the vehicle 100 to perform the work in the current manufacturing process. The deficiency determination unit 213 determines that the deficiency KS has occurred in the measured appearance information MG in a case where the current manufacturing process of the vehicle 100 indicated in the process information acquired from the process management device 400 is the manufacturing process in which the worker gets on the vehicle 100 to perform the work. The deficiency determination unit 213 may acquire, in advance, the process information including information on a place where a manufacturing process in which the worker gets on the vehicle 100 to perform the work is executed from the process management device 400, and determine that the deficiency KS has occurred in the measured appearance information MG in a case where the vehicle 100 passes through the place where the manufacturing process in which the worker gets on the vehicle 100 to perform the work is executed.

### Determination Method A3

In the determination method A3, the deficiency determination unit 213 determines that the deficiency KS has occurred in the measured appearance information MG in a case where the deficiency determination unit 213 predicts that the deficiency KS will occur in the measured appearance information MG. For example, a camera is installed at a place where each of the manufacturing processes of the vehicle 100 is executed, and the deficiency determination unit 213 acquires the number of workers present in the vicinity of the vehicle 100 in the current manufacturing process by analyzing an image acquired from the camera, and predicts that the deficiency KS will occur in the measured appearance information MG in a case where the number of workers present in the vicinity of the vehicle 100 is equal to or more than the predetermined number. The deficiency determination unit 213 may determine whether the worker gets on the vehicle 100 by analyzing the image acquired from the camera, and predict that the deficiency KS will occur in the measured appearance information MG in a case where the manufacturing process is the manufacturing process in which the worker gets on the vehicle 100 to perform the work.

### Determination Method A4

In the determination method A4, the deficiency determination unit 213 determines that the deficiency KS has occurred in the measured appearance information MG in a case where the deficiency KS that has occurred in the measured appearance information MG is detected. The deficiency determination unit 213 detects that the deficiency KS has occurred in the measured appearance information MG by using measured appearance information MG1 used for current matching, measured appearance information MG2 used for matching N times ago (N is a natural number), and the movement information MV stored in the memory 202. Here, the measured appearance information MG1 used for the current matching is the measured appearance information MG measured by the external sensor 300 at time T1, and the measured appearance information MG2 used for the matching N times ago is the measured appearance information MG measured by the external sensor 300 at time T2 earlier than time T1. As shown in FIG. 7, the movement information MV includes time-series data of the speed and the steering angle of the vehicle 100 measured by the internal sensor group 140 from time T2 to time T1. As shown in FIG. 8, first, the deficiency determination unit 213 decides a bounding box BB surrounding a portion, corresponding to the vehicle 100, in the measured appearance information MG2 used for the matching N times ago. A portion, corresponding to the vehicle 100, in the measured appearance information MG2 is a portion that matches with the reference appearance information RG in the matching. Next, the deficiency determination unit 213 calculates a movement amount and a rotation amount of the vehicle 100 between time T2 and time T1 by using the movement information MV stored in the memory 202. The deficiency determination unit 213 moves the bounding box BB by the movement amount of the vehicle 100 from time T2 to time T1, and rotates the bounding box BB by the rotation amount of the vehicle 100 from time T2 to time T1. The deficiency determination unit 213 acquires the number of point clouds of the portion surrounded by the bounding box BB in the measured appearance information MG1 used for the current matching. The number of point clouds in the portion surrounded by the bounding box BB is smaller in a case where the deficiency KS has occurred in the measured appearance information MG1 than in a case where the deficiency KS has not occurred. Therefore, the deficiency determination unit 213 detects that the deficiency KS has occurred in the measured appearance information MG1 in a case where the number of point clouds in the portion surrounded by the bounding box BB is equal to or less than a predetermined number.

In the determination method A4, the deficiency determination unit 213 can calculate the movement amount of the vehicle 100 by Expression (1). In Expression (1), x represents the movement amount of the vehicle 100 in an X direction, y represents the movement amount of the vehicle 100 in a Y direction, t represents time, v represents the speed of the vehicle 100, and θ represents the steering angle of the vehicle 100. Expression (1) represents the movement amount of the vehicle 100 in two seconds.

$$( x ( t ) , y ( t ) ) = ( x ( t - 2 ) + {\int }_{t - 2}^{t} v ( t ) cos θ dt , y ( t - 2 ) + {\int }_{t - 2}^{t} v ( t ) sin θ dt ) \qquad ( 1 )$$

As shown in FIG. 5, in a case where a determination is made in step S120 that the deficiency KS has occurred in the measured appearance information MG, the complement unit 214 complements the deficiency in the measured appearance information MG in step S130. In the present embodiment, the complement unit 214 complements the deficiency in the measured appearance information MG1 used for the current matching by using the measured appearance information MG2 used for the matching N times ago and the movement information MV stored in the memory 202. Here, the measured appearance information MG1 used for the current matching is the measured appearance information MG measured by the external sensor 300 at time T1, and the measured appearance information MG2 used for the matching N times ago is the measured appearance information MG measured by the external sensor 300 at time T2 earlier than time T1. The number of N is preferably smaller. The number of N is preferably 1. As shown in FIG. 7, the movement information MV includes the time-series data of the speed and the steering angle of the vehicle 100 measured by the internal sensor group 140 from time T2 to time T1. As shown in FIG. 9, first, the complement unit 214 calculates the movement amount and the rotation amount of the vehicle 100 between time T2 and time T1 by using the movement information MV stored in the memory 202. Next, the complement unit 214 moves the measured appearance information MG2 by the movement amount of the vehicle 100 from time T2 to time T1, and rotates the measured appearance information MG2 by the rotation amount of the vehicle 100 from time T2 to time T1. By moving and rotating the measured appearance information MG2, a portion, corresponding to the vehicle 100, in the measured appearance information MG2 overlaps a deficient portion in the measured appearance information MG1, and the deficiency KS in the measured appearance information MG1 is complemented. The complement unit 214 may move and rotate the entire measured appearance information MG2, may move and rotate solely a portion, corresponding to the vehicle 100, in the measured appearance information MG2, or may move and rotate solely a portion, corresponding to the deficient portion in the measured appearance information MG1, in the measured appearance information MG2. The complement unit 214 may move the measured appearance information MG2 without rotating the measured appearance information MG2 when the complement unit 214 complements the deficiency KS in the measured appearance information MG1.

In step S140, the estimation unit 215 estimates the position and the orientation of the vehicle 100 by executing the matching using the measured appearance information MG and the reference appearance information RG. When the complement of the deficiency KS is not executed in step S130, the estimation unit 215 estimates the position and the orientation of the vehicle 100 by executing the matching between the measured appearance information MG in which the complement of the deficiency KS is not executed with the reference appearance information RG. When the complement of the deficiency KS is executed in step S130, the estimation unit 215 estimates the position and the orientation of the vehicle 100 by executing the matching between the measured appearance information MG in which the complement of the deficiency KS is executed with the reference appearance information RG. As a method of the matching, for example, a normal distributions transform (NDT) or an iterative closest point (ICP) can be used. The estimation unit 215 can estimate the position and the orientation of the vehicle 100 in a coordinate system of the external sensor 300 by executing the matching. A position and an orientation of the external sensor 300 are fixed, and a positional relationship between the coordinate system of the external sensor 300 and the global coordinate system GC is known. Therefore, the estimation unit 215 can convert the position and the orientation of the vehicle 100 in the coordinate system of the external sensor 300 into the position and the orientation of the vehicle 100 in the global coordinate system GC. A process of acquiring the measured appearance information MG may be referred to as an appearance information acquisition process. A process of acquiring the movement information MV may be referred to as a movement information acquisition process. A process of determining whether the deficiency has occurred in the measured appearance information MG may be referred to as a determination process. A process of complementing the deficiency KS in the measured appearance information MG may be referred to as a complement process. A process of estimating at least one of the position and the orientation of the vehicle 100 may be referred to as an estimation process.

In step S150, the remote controller 216 decides a target position to which the vehicle 100 should head next. In the present embodiment, the target position is represented by the coordinates of X, Y, and Z in the global coordinate system GC. A reference route RR that is a route along which the vehicle 100 should travel is stored in advance in the memory 202 of the server device 200. The route is represented by a node indicating a departure point, a node indicating a passing point, a node indicating a destination, and a link connecting the respective nodes. The remote controller 216 decides the target position to which the vehicle 100 should head next by using the vehicle position information and the reference route RR. The remote controller 216 decides the target position on the reference route RR ahead of a current position of the vehicle 100.

In step S160, the remote controller 216 generates the traveling control signal for causing the vehicle 100 to travel toward the decided target position. The remote controller 216 calculates a traveling speed of the vehicle 100 from the transition of the position of the vehicle 100, and compares the calculated traveling speed with a target speed. As a whole, the remote controller 216 decides the acceleration such that the vehicle 100 is accelerated when the traveling speed is lower than the target speed, and decides the acceleration such that the vehicle 100 is decelerated when the traveling speed is higher than the target speed. The remote controller 216 decides the steering angle and the acceleration such that the vehicle 100 does not deviate from the reference route RR when the vehicle 100 is located on the reference route RR, and decides the steering angle and the acceleration such that the vehicle 100 returns to the reference route RR when the vehicle 100 is not located on the reference route RR, in other words, when the vehicle 100 deviates from the reference route RR.

In step S170, the remote controller 216 transmits the generated traveling control signal to the vehicle 100. The server device 200 repeatedly executes, at a predetermined cycle, the acquisition of the vehicle position information, the decision of the target position, the generation of the traveling control signal, and the transmission of the traveling control signal.

In step S180, the traveling controller 196 receives the traveling control signal transmitted from the server device 200. In step S190, the traveling controller 196 controls the actuator group 120 by using the received traveling control signal to cause the vehicle 100 travel at the acceleration and the steering angle represented by the traveling control signal. The vehicle control device 110 repeatedly executes, at a predetermined cycle, the reception of the traveling control signal and the control of the actuator group 120.

The movement amount and the rotation amount of the vehicle 100, which are calculated from the movement information MV as the measurement result of the internal sensor group 140 mounted in the vehicle 100, may deviate from an actual movement amount and an actual rotation amount of the vehicle 100. Therefore, in a case where the measured appearance information MG2 used for the matching N times ago is modified (the bounding box BB is moved and rotated) by the movement amount and the rotation amount calculated from the movement information MV to complement the deficiency KS in the measured appearance information MG1 used for the current matching, a deviation may occur between the measured appearance information MG1 and the measured appearance information MG2. Therefore, in a case where the deficiency KS is complemented in the measured appearance information MG2 used to complement the deficiency KS in the measured appearance information MG1, there is a possibility that the estimation accuracy of the position and the orientation of the vehicle 100 is decreased. In this way, when the complement of the measured appearance information MG using the complemented measured appearance information MG is repeatedly executed, there is a possibility that the amount of decrease in the estimation accuracy of the position and the orientation of the vehicle 100 is increased. Therefore, in the present embodiment, the remote controller 216 decelerates or stops the vehicle 100 in a case where the complement of the deficiency KS in the measured appearance information MG is repeatedly executed a predetermined number of times. The predetermined number of times may be fixed in advance or may be optionally decided (changed) by the remote controller 216. The remote controller 216 can decide the predetermined number of times by using, for example, at least one of the following number-of-times decision methods B1 to B3.

### Number-of-Times Decision Method B1

In the number-of-times decision method B1, the remote controller 216 decides the number of times in accordance with a movement state of the vehicle 100. It is not preferable to move the vehicle 100 at a high speed in a state where the estimation accuracy of the position and the orientation of the vehicle 100 is decreased, since there is a high possibility that the vehicle 100 comes into contact with the obstacle or the like. Therefore, the remote controller 216 may reduce the number of times as the speed of the vehicle 100 is increased. In this case, it is possible to reduce the possibility that the vehicle 100 comes into contact with the obstacle or the like. In addition, in a case where the vehicle 100 is making a turn, the behavior of the vehicle 100 is likely to be unstable. Therefore, the remote controller 216 may reduce the predetermined number of times in a case where the vehicle 100 is making a turn than in a case where the vehicle 100 is traveling straight. In this case, a situation can be suppressed in which the behavior of the vehicle 100 is unstable.

### Number-of-Times Decision Method B2

In the number-of-times decision method B2, the remote controller 216 decides the predetermined number of times in accordance with the magnitude of the deficiency KS in the measured appearance information MG. The estimation accuracy of the position and the orientation of the vehicle 100 is likely to be lower as the deficiency KS in the measured appearance information MG is larger. Therefore, the remote controller 216 may reduce the number of times as the deficiency KS in the measured appearance information MG is increased. In this case, a significant decrease in the estimation accuracy of the position and the orientation of the vehicle 100 can be suppressed.

### Number-of-Times Decision Method B3

In the number-of-times decision method B3, the remote controller 216 decides the predetermined number of times in accordance with a distance between the external sensor 300 and the vehicle 100. The estimation accuracy of the position and the orientation of the vehicle 100 is likely to be lower as the distance between the external sensor 300 and the vehicle 100 is larger. Therefore, the remote controller 216 may reduce the predetermined number of times as the distance between the external sensor 300 and the vehicle 100 is increased. In this case, a significant decrease in the estimation accuracy of the position and the orientation of the vehicle 100 can be suppressed.

With the system 10 according to the present embodiment described above, even when the deficiency KS has occurred in the measured appearance information MG acquired from the external sensor 300, the deficiency KS in the measured appearance information MG can be complemented. Therefore, a situation can be suppressed in which a correct estimation result of the position or the orientation of the vehicle 100 cannot be obtained due to the occurrence of the deficiency KS in the measured appearance information MG.

### B. Second Embodiment

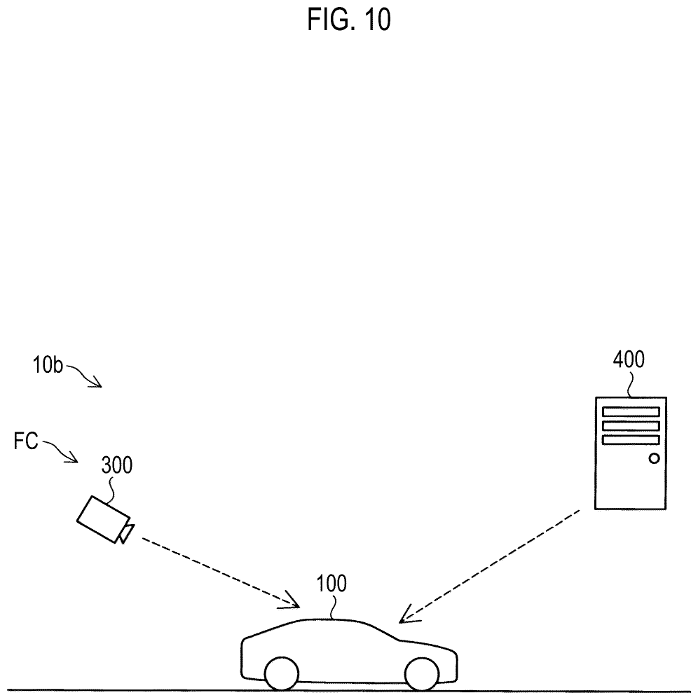

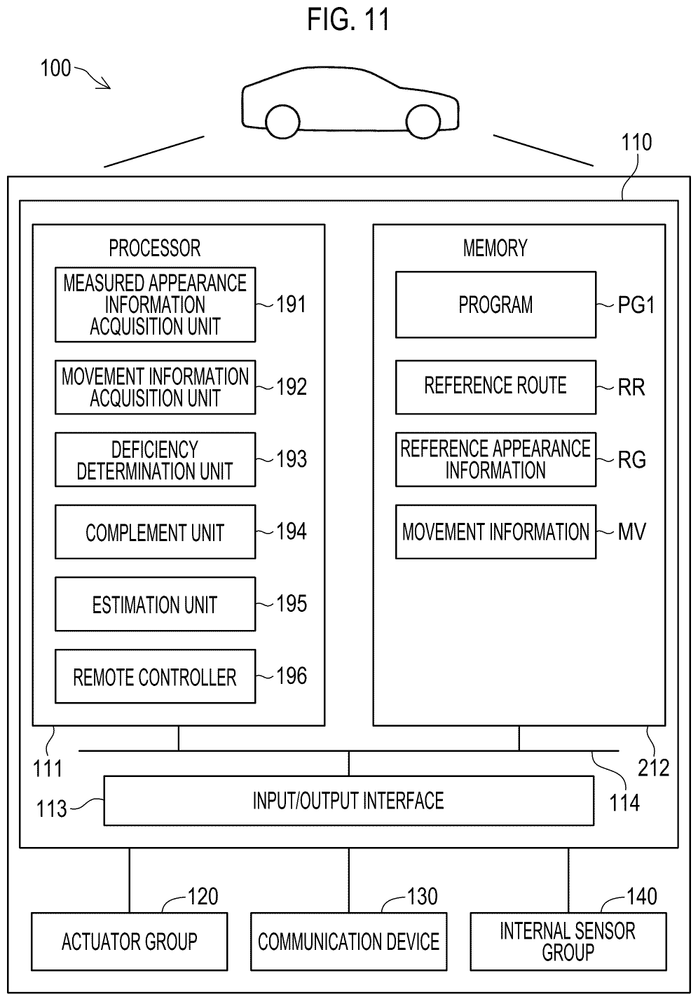

FIG. 10 is a diagram showing a configuration of a system 10b according to a second embodiment. FIG. 11 is a diagram showing a configuration of the vehicle 100 according to the second embodiment. As shown in FIG. 10, the second embodiment is different from the first embodiment in that the system 10b does not include the server device 200 and that the vehicle 100 is configured to be travel via the autonomous control of the vehicle 100 instead of the remote control. Other configurations are the same as the configurations of the first embodiment unless otherwise described. In the present embodiment, the vehicle control device 110 can be regarded as a “device” according to the present disclosure, and the traveling controller 196 can be regarded as a “controller” according to the present disclosure.

As shown in FIG. 11, in the present embodiment, the communication device 130 communicates with the external sensor 300 and the process management device 400 via wireless communication. The reference route RR and the reference appearance information RG are stored in advance in the memory 112 of the vehicle control device 110. In the present embodiment, the processor 111 of the vehicle control device 110 functions as a measured appearance information acquisition unit 191, a movement information acquisition unit 192, a deficiency determination unit 193, a complement unit 194, an estimation unit 195, and a traveling controller 196 by executing the computer program PG1 stored in advance in the memory 112.

The measured appearance information acquisition unit 191 acquires the measured appearance information MG from the external sensor 300. The movement information acquisition unit 192 acquires the measurement result of the internal sensor group 140, in other words, the movement information MV, and records the movement information MV in the memory 112. The deficiency determination unit 193 determines whether the deficiency has occurred in the measured appearance information MG acquired by the measured appearance information acquisition unit 191. The complement unit 194 uses the movement information MV to complement the deficiency KS in the measured appearance information MG in a case where a determination is made that the deficiency KS has occurred in the measured appearance information MG. The estimation unit 195 estimates at least one of the position and the orientation of the vehicle 100 by comparing the measured appearance information MG with the reference appearance information RG. The estimation unit 195 estimates both the position and the orientation of the vehicle 100. In a case where the deficiency determination unit 193 does not determine that the deficiency KS has occurred in the measured appearance information MG, the estimation unit 195 compares the measured appearance information MG in which the deficiency KS is not complemented by the complement unit 194 with the reference appearance information RG. In a case where the deficiency determination unit 193 determines that the deficiency KS has occurred in the measured appearance information MG, the estimation unit 195 compares the measured appearance information MG in which the deficiency KS is complemented by the complement unit 194 with the reference appearance information RG. In the present embodiment, the traveling controller 196 generates the traveling control signal for causing the vehicle 100 to travel by using the estimation result of the estimation unit 195. The traveling controller 196 controls the actuator group 120 by using the traveling control signal generated by the traveling controller 196.

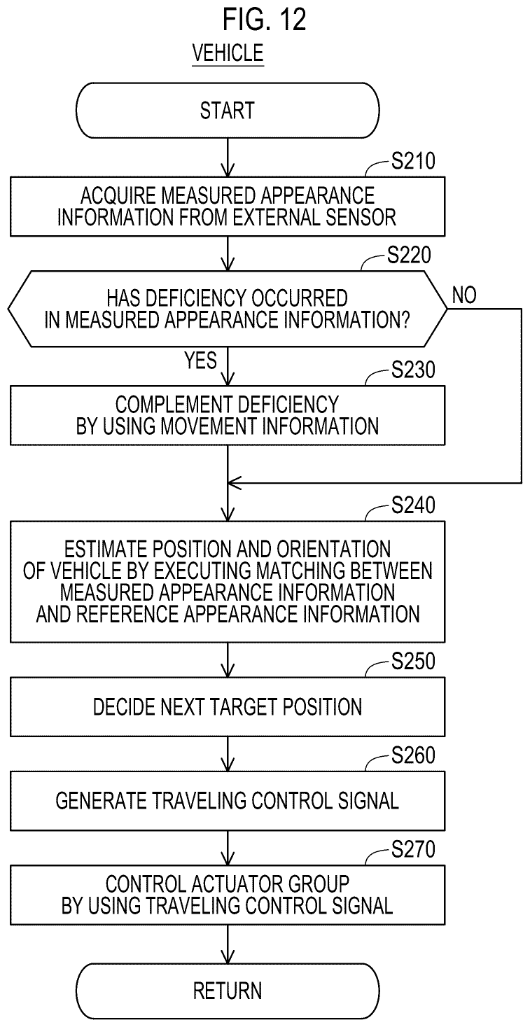

FIG. 12 is a flowchart showing a processing procedure of traveling control of the vehicle 100 according to the second embodiment. Steps S210 to S270 are repeatedly executed by the processor 111 of the vehicle control device 110. In step S210, the measured appearance information acquisition unit 191 acquires the measured appearance information MG from the external sensor 300.

In step S220, the deficiency determination unit 213 determines whether the deficiency KS has occurred in the measured appearance information MG. The deficiency determination unit 193 determines whether the deficiency KS has occurred in the measured appearance information MG by using at least one of the determination methods A1 to A4.

When a determination is made in step S220 that the deficiency KS has occurred in the measured appearance information MG, the deficiency determination unit 193 advances the processing to step S230. When a determination is not made in step S220 that the deficiency KS has occurred in the measured appearance information MG, the deficiency determination unit 193 skips step S230 and advances the processing to step S240.

In step S230, the complement unit 194 complements the deficiency in the measured appearance information MG. In the present embodiment, the complement unit 194 complements the deficiency in the measured appearance information MG used for the current matching by using the measured appearance information MG used for the matching N times ago and the movement information MV stored in the memory 112.

In step S240, the estimation unit 195 estimates the position and the orientation of the vehicle 100 by executing the matching using the measured appearance information MG and the reference appearance information RG. When the complement of the deficiency KS is not executed in step S230, the estimation unit 195 estimates the position and the orientation of the vehicle 100 by executing the matching between the measured appearance information MG in which the complement of the deficiency KS is not executed with the reference appearance information RG. When the complement of the deficiency KS is executed in step S230, the estimation unit 195 estimates the position and the orientation of the vehicle 100 by executing the matching between the measured appearance information MG in which the complement of the deficiency KS is executed with the reference appearance information RG.

In step S250, the traveling controller 196 decides the target position to which the vehicle 100 should head next. In step S260, the traveling controller 196 generates the traveling control signal for causing the vehicle 100 to travel toward the decided target position. In step S270, the traveling controller 196 controls the actuator group 120 by using the generated traveling control signal to cause the vehicle 100 to travel in accordance with the parameter represented by the traveling control signal. The processor 111 of the vehicle control device 110 repeatedly executes the acquisition of the vehicle position information, the decision of the target position, the generation of the traveling control signal, and the control of the actuator group 120 at a predetermined cycle.

With the system 10b according to the present embodiment described above, the vehicle 100 can be caused to travel via the autonomous control of the vehicle 100 without the need for the server device 200 to remotely control the vehicle 100. Further, in the present embodiment, as in the first embodiment, even when the deficiency KS has occurred in the measured appearance information MG acquired from the external sensor 300, the deficiency KS in the measured appearance information MG can be complemented. Therefore, a situation can be suppressed in which a correct estimation result of the position or the orientation of the vehicle 100 cannot be obtained due to the occurrence of the deficiency KS in the measured appearance information MG.

### C. Other Embodiments

(C1) In the first and second embodiments, the external sensor 300 is the LiDAR. In contrast, the external sensor 300 may be the camera. In this case, the estimation units 215, 195 may estimate the position and the orientation of the vehicle 100 by image matching using the image of the vehicle 100 output from the camera, instead of the point cloud matching using the three-dimensional point cloud data of the vehicle 100 output from the LiDAR.

(C2) In the first and second embodiments, the server device 200 executes the processing from the acquisition of the vehicle position information of the vehicle 100 to the generation of the traveling control signal. On the other hand, the vehicle 100 may execute at least a part of the processing from the acquisition of the vehicle position information of the vehicle 100 to the generation of the traveling control signal. For example, the following forms (1) to (3) may be adopted.

(1) The server device 200 may acquire the vehicle position information of the vehicle 100, decide the target position to which the vehicle 100 should head next, and generate the route from the current position of the vehicle 100 represented by the acquired vehicle position information to the target position. The server device 200 may generate a route to the target position between the current position and the destination or may generate a route to the destination. The server device 200 may transmit the generated route to the vehicle 100. The vehicle 100 may generate the traveling control signal for causing the vehicle 100 to travel on the route received from the server device 200, and control the actuator group 120 by using the generated traveling control signal.

(2) The server device 200 may acquire the vehicle position information of the vehicle 100 and transmit the acquired vehicle position information to the vehicle 100. The vehicle 100 may decide the target position to which the vehicle 100 should head next, generate the route from the current position of the vehicle 100 represented by the received vehicle position information to the target position, generate the traveling control signal such that the vehicle 100 travels on the generated route, and control the actuator group 120 by using the generated traveling control signal. In each of the above-described embodiments, the vehicle operation information may be the route from the current position of the vehicle 100 to the target position.

(3) In the above-described forms (1) and (2), an internal sensor may be mounted in the vehicle 100, and a detection result output from the internal sensor may be used for at least one of the generation of the route and the generation of the traveling control signal. The internal sensor may include, for example, a camera, a LiDAR, a millimeter wave radar, an ultrasound sensor, a GPS sensor, an acceleration sensor, and a gyro sensor. For example, in the above-described form (1), the server device 200 may acquire the detection result of the internal sensor and reflect the detection result of the internal sensor in the route when the route is generated. In the above-described form (1), the vehicle 100 may acquire the detection result of the internal sensor and reflect the detection result of the internal sensor to the traveling control signal when the traveling control signal is generated. In the above-described form (2), the vehicle 100 may acquire the detection result of the internal sensor and reflect the detection result of the internal sensor to the route when the route is generated. In the above-described form (2), the vehicle 100 may acquire the detection result of the internal sensor and reflect the detection result of the internal sensor to the traveling control signal when the traveling control signal is generated.

(C3) In the first and second embodiments, an internal sensor may be mounted in the vehicle 100, and a detection result output from the internal sensor may be used for at least one of the generation of the route and the generation of the traveling control signal. For example, the vehicle 100 may acquire the detection result of the internal sensor and reflect the detection result of the internal sensor to the route when the route is generated. The vehicle 100 may acquire the detection result of the internal sensor and reflect the detection result of the internal sensor to the traveling control signal when the traveling control signal is generated.

(C4) In the second embodiment, the vehicle 100 acquires the vehicle position information by using the detection result of the external sensor 300. On the other hand, the internal sensor may be mounted in the vehicle 100, and the vehicle 100 may acquire the vehicle position information by using the detection result of the internal sensor, decide the target position to which the vehicle 100 should head next, generate the route from the current position of the vehicle 100 represented by the acquired vehicle position information to the target position, generate the traveling control signal for traveling on the generated route, and control the actuator group 120 by using the generated traveling control signal. In this case, the vehicle 100 can travel without using the detection result of the external sensor 300 at all. The vehicle 100 may acquire a target arrival time or traffic jam information from the outside of the vehicle 100 and reflect the target arrival time or the traffic jam information to at least one of the route and the traveling control signal.

(C5) In the first and second embodiments, the server device 200 automatically generates the traveling control signal to be transmitted to the vehicle 100. On the other hand, the server device 200 may generate the traveling control signal to be transmitted to the vehicle 100 in response to an operation of an external operator who is located outside the vehicle 100. For example, the external operator may operate an operation device including a display that displays the captured image output from the camera as the external sensor 300, a steering wheel, an accelerator pedal, and a brake pedal for remotely operating the vehicle 100, and a communication device that communicates with the server device 200 via wired communication or wireless communication, and the server device 200 may generate the traveling control signal in response to the operation applied to the operation device.

(C6) In the first and second embodiments, the vehicle 100 need solely have a configuration capable of moving via the unmanned driving, and may have, for example, a form of a platform having a configuration described below. Specifically, the vehicle 100 need solely include at least the vehicle control device 110 and the actuator group 120, in order to exhibit the three functions of “traveling”, “turning”, and “stopping” via the unmanned driving. In a case where the vehicle 100 acquires the information from the outside for the unmanned driving, the vehicle 100 need solely further include the communication device 130. That is, the vehicle 100 that can move via the unmanned driving need not be mounted with at least a part of the interior components, such as the driver's seat and the dashboard, need not be mounted with at least a part of the exterior components, such as the bumper and the fender mirror, and need not be mounted with the bodyshell. In this case, the remaining components, such as the bodyshell, may be mounted in the vehicle 100 before the vehicle 100 is shipped from a factory FC, or the remaining components, such as the bodyshell, may be mounted in the vehicle 100 after the vehicle 100 is shipped from the factory FC in a state where the remaining components, such as the bodyshell, are not mounted in the vehicle 100. Each component may be mounted from any direction, such as the upper side, the lower side, the front side, the rear side, the right side, or the left side of the vehicle 100, and may be mounted from the same direction or different directions. The position decision can be made for the form of the platform in the same manner as the vehicle 100 according to the first embodiment.

(C7) The vehicle 100 may be manufactured by combining a plurality of modules. The module means a unit configured by a plurality of components assembled depending on the part or the function of the vehicle 100. For example, the platform of the vehicle 100 may be manufactured by combining a front module that constitutes a front portion of the platform, a center module that constitutes a center portion of the platform, and a rear module that constitutes a rear portion of the platform. In addition, the number of modules constituting the platform is not limited to three, and may be two or less or four or more. In addition to or instead of the components constituting the platform, the components constituting a portion of the vehicle 100 that is different from the platform may be modularized. In addition, various modules may include any exterior component, such as a bumper or a grille, or any interior component, such as a seat or a console. The present disclosure is not limited to the vehicle 100, a mobile body of any aspect may be manufactured by combining the modules. Such a module may be manufactured, for example, by joining the components via welding, a fastener, or the like, or may be manufactured by integrally molding at least a part of the components constituting the modules as one component via casting. A molding method of integrally molding one component, particularly a relatively large component, is also called giga casting or mega casting. For example, the front module, the center module, and the rear module may be manufactured by using giga casting.

(C8) The transport of the vehicle 100 using the traveling of the vehicle 100 via the unmanned driving is also referred to as “autonomous transport”. A configuration for implementing the autonomous transport is also referred to as “vehicle remote control autonomous driving transport system”. A production method of producing the vehicle 100 by using the autonomous transport is also referred to as “autonomous production”. In the autonomous production, for example, at the factory FC that manufactures the vehicle 100, at least a part of the transport of the vehicle 100 is implemented by the autonomous transport.

(C9) In the first and second embodiments, a part or all of the functions and the processing that are implemented by software may be implemented by hardware. Alternatively, a part or all of the functions and the processing that are implemented by hardware may be implemented by software. As the hardware for implementing various functions in each of the above-described embodiments, for example, various circuits, such as an integrated circuit or a discrete circuit, may be used.

The present disclosure is not limited to the above-described embodiments, and can be implemented with various configurations without departing from the gist of the present disclosure. For example, the technical features in the embodiments corresponding to the technical features in the respective forms described in SUMMARY can be replaced or combined as appropriate to solve a part or all of the above-described objects, or to achieve a part or all of the above-described effects. In a case where the technical features are not described as being always needed in the present specification, the features can be deleted as appropriate.

What is claimed is:

1. A device comprising:
an appearance information acquisition unit configured to acquire first measured appearance information on an appearance of a mobile body from a detector configured to measure the appearance of the mobile body;
a movement information acquisition unit configured to acquire movement information on movement of the mobile body;
a determination unit configured to determine whether a deficiency has occurred in the first measured appearance information;
a complement unit configured to, in a case where the determination unit determines that the deficiency has occurred, use the movement information to complement the deficiency in the first measured appearance information; and
an estimation unit configured to estimate at least one of a position and an orientation of the mobile body by comparing reference appearance information on the appearance of the mobile body with the first measured appearance information, the estimation unit being configured to, in the case where the determination unit determines that the deficiency has occurred, compare the first measured appearance information complemented by the complement unit with the reference appearance information.

2. The device according to claim 1, wherein the determination unit is configured to, in a case where the deficiency is detected from the first measured appearance information, determine that the deficiency has occurred in the first measured appearance information.

3. The device according to claim 1, wherein the determination unit is configured to, in a case where the determination unit predicts that the deficiency will occur in the first measured appearance information, determine that the deficiency has occurred in the first measured appearance information.

4. The device according to claim 3, wherein the determination unit is configured to, in at least one of a case where the mobile body is located at a predetermined place and a case where the mobile body passes through the predetermined place, predict that the deficiency will occur in the first measured appearance information.

5. The device according to claim 4, wherein the predetermined place is a place where a predetermined number of workers are present.

6. The device according to claim 4, wherein the predetermined place is a place where a worker gets on the mobile body to perform work.

7. The device according to claim 1, further comprising a controller configured to, in a case where the complement of the deficiency in the first measured appearance information is repeated a predetermined number of times, decelerate or stop the mobile body.

8. The device according to claim 7, wherein the controller is configured to change the predetermined number of times in accordance with a movement state of the mobile body.

9. The device according to claim 8, wherein the controller is configured to execute at least one of
(A) reducing the predetermined number of times as a speed of the mobile body is increased, and
(B) reducing the predetermined number of times in a case where the mobile body is making a turn than in a case where the mobile body is traveling straight.

10. The device according to claim 7, wherein the controller is configured to change the predetermined number of times in accordance with magnitude of the deficiency.

11. The device according to claim 10, wherein the controller is configured to reduce the predetermined number of times as the magnitude of the deficiency is increased.

12. The device according to claim 7, wherein the controller is configured to change the predetermined number of times in accordance with a distance between the detector and the mobile body.

13. The device according to claim 12, wherein the controller is configured to reduce the predetermined number of times as the distance between the detector and the mobile body is increased.

14. The device according to claim 1, wherein the first measured appearance information is three-dimensional point cloud data measured by the detector within a predetermined period.

15. The device according to claim 1, further comprising a storage medium configured to store the reference appearance information,
wherein the reference appearance information is three-dimensional point cloud data generated by using CAD data representing the appearance of the mobile body.

16. The device according to claim 1, further comprising a storage medium configured to store the movement information,
wherein the complement unit is configured to complement the deficiency in the first measured appearance information used for current matching by using second measured appearance information used for matching N times ago and the movement information.

17. The device according to claim 1, wherein the complement unit is configured to complement the deficiency in the first measured appearance information by modifying information on a movement amount of the mobile body in second measured appearance information by an amount corresponding to a movement amount of the mobile body within a predetermined period, and modifying information on a rotation amount of the mobile body in the second measured appearance information by an amount corresponding to a rotation amount of the mobile body within the predetermined period.

18. The device according to claim 1, wherein:
the estimation unit is configured to, in a case where the complement unit does not complement the deficiency, estimate the position and the orientation of the mobile body by executing matching between the first measured appearance information in which the deficiency is not complemented and the reference appearance information; and
the estimation unit is configured to, in the case where the complement unit complements the deficiency, estimate the position and the orientation of the mobile body by comparing the first measured appearance information in which the deficiency is complemented, with the reference appearance information.

19. A system comprising:
a detector configured to measure an appearance of a mobile body;
an appearance information acquisition unit configured to acquire measured appearance information on the appearance of the mobile body from the detector;
a movement information acquisition unit configured to acquire movement information on movement of the mobile body;
a determination unit configured to determine whether a deficiency has occurred in the measured appearance information;
a complement unit configured to, in a case where the determination unit determines that the deficiency has occurred, use the movement information to complement the deficiency in the measured appearance information; and
an estimation unit configured to estimate at least one of a position and an orientation of the mobile body by comparing reference appearance information on the appearance of the mobile body with the measured appearance information, the estimation unit being configured to, in the case where the determination unit determines that the deficiency has occurred, compare the measured appearance information complemented by the complement unit with the reference appearance information.

20. A method comprising:
acquiring measured appearance information on an appearance of a mobile body by measuring the appearance of the mobile body;
acquiring movement information on movement of the mobile body;
determining whether a deficiency has occurred in the measured appearance information;
complementing, in a case where a determination is made that the deficiency has occurred, the deficiency in the measured appearance information by using the movement information; and
estimating, in the case where the determination is made that the deficiency has occurred, at least one of a position and an orientation of the mobile body by comparing the complemented measured appearance information with reference appearance information on the appearance of the mobile body.
